(19) United States
(12) Patent Application Publication
(10) Pub. No.: US 2013/0298967 A1
(43) Pub. Date: Nov. 14, 2013

(54) TANDEM SOLAR CELL STRUCTURE AND FABRICATION METHOD THEREOF

(71) Applicants: Tien-Jung HUANG, Taipei City (TW); Jui-yao CHIEN, Hsinchu City (TW)

(72) Inventors: Tien-Jung HUANG, Taipei City (TW); Jui-yao CHIEN, Hsinchu City (TW)

(73) Assignee: GCSOL TECH CO., LTD., Taichung County (TW)

(21) Appl. No.: 13/591,228

(22) Filed: Aug. 22, 2012

(30) Foreign Application Priority Data
May 10, 2012 (TW) 101116684

(51) Int. Cl. H01L 31/042; H01L 31/18

(52) U.S. Cl. 136/249; 438/67; 257/E31.052

(57) ABSTRACT

A tandem solar cell structure includes a substrate, a conductive layer, a bottom solar cell combination and a top solar cell, The bottom solar cell combination includes a plurality of solar cell units and is disposed on the substrate. A conductive layer is disposed between the top solar cell and the bottom solar cell combination. The top solar cell is connected to one of the solar cell units in series. A wide energy distribution of the solar radiation can be absorbed through the tandem solar cell structure. The electrical series connection of the top solar cell and the solar cell units of the bottom solar cell combination reduces current mismatch between the top and bottom cells and enhances the overall system open circuit voltage due to more units in the bottom cell combination. The efficiency of the tandem solar cell structure is therefore improved considerably.

### RELATED APPLICATIONS

The application claims priority to Taiwan Application Serial Number 101116684, filed May 10, 2012, which is herein incorporated by reference.

### BACKGROUND

1. Technical Field

The present disclosure relates to a tandem solar cell structure and fabrication method thereof. More particularly, the present disclosure relates to a tandem solar cell structure that can reduce current mismatch between a top solar cell and a bottom solar cell combination and can enhance the open circuit voltage (Voc).

2. Description of Related Art

A demand on exploiting new energy sources increase dramatically in that the energy shortage issue is getting more and more serious. The energy of a solar radiation from the sun to the surface through the atmosphere of the earth is about 1.8×10¹⁴ kW. Such energy is around one hundred thousand times of than the annual worldwide demand in electric power. Efficiently utilizing the solar energy will be of great help in solving the issue of energy shortage.

A solar cell is an energy conversion device. The purpose of the solar cell is to convert a solar energy to an electrical energy. In principle, an electricity of a solar cell is generated based on the photovoltaic effect. A solar cell is basically consisting of a p-type and an n-type semiconductor. When a solar radiation is incident to the solar cell, the energy higher than a bandgap of the semiconductor is absorbed. As such an electron-hole pair is generated, and thus an electric current.

The spectrum of the solar radiation ranges from 0.3 micron (μm) to a few microns, which is equal to an energy distribution from 0.4 eV (Electronic Volt) to 4 eV. In this regard, the solar radiation distributes in a wide range. A conventional solar cell structure is made of silicon (Si)-based materials. The bandgap energy of Si is about 1.1 eV in the room temperature. Only the solar energy larger than 1.1 eV can be absorbed by the solar cell structure, and the solar energy lower than 1.1 eV cannot be absorbed, which leads to low photoelectric conversion efficiency. To address this issue, a tandem solar cell structure is disclosed. The concept of the tandem solar cell structure is to combine two semiconductor devices which have different bandgap energy into one solar cell structure. Therefore, different energy regions of the solar radiation can be absorbed by the two semiconductors having different bandgap energy and the photoelectric conversion efficiency can be enlarged. Although the bandwidth distribution of energy absorption can be enlarged, there exists a current density mismatch between the top solar cell and the bottom solar cell of the tandem solar cell structure. Such current mismatch issue will still lead to low photoelectric conversion efficiency.

### SUMMARY

According to one aspect of the present disclosure, a tandem solar cell structure is provided. A bottom solar cell combination and a top solar cell are disposed on a substrate. A conductive layer is disposed between the top solar cell and the bottom solar cell combination. The bottom solar cell combination comprises a plurality of solar cell units, and the solar cell units are connected in series with each other. The top solar cell is only connected to one of the solar cell units in series. The top solar cell has bandgap energy higher than bandgap energy of the solar cell units of the bottom solar cell combination.

According to another aspect of the present disclosure, a fabrication method applicable to the tandem solar cell structure of the present disclosure is provided. The fabrication method comprises the following steps: forming a solar cell body; cutting the solar cell body into a plurality of solar cell units, wherein a gap formed between each of the solar cell units; connecting the solar cell units with each other in series to form the bottom solar cell combination; forming a top solar cell and connecting the top solar cell with one of the solar cell units in series.

According to still another aspect of the present disclosure, the substrate is a transparent substrate or a bendable substrate. Besides, the substrate is made of glass, metal or organic materials.

According to still another aspect of the present disclosure, the method of forming the solar cell units can be laser scribing, chemical etching or reactive ion etching.

According to still another aspect of the present disclosure, the solar cell units of the bottom solar cell combination are made of III-V group semiconductor compounds, II-VI group semiconductor compounds, organic semiconductor compounds, nanoscale materials, CIGS (CuInGaS)-based materials or CIS (CuInSe)-based materials.

According to still another aspect of the present disclosure, the conductive layer is a tunneling-junction layer, and the conductive layer is made of transparent oxide materials or thin and transparent metal materials.

According to still another aspect of the present disclosure, the top solar cell is made of a-Si-based materials, CGS (CuGaSe)-based materials or a-Si/μc-SiC multi-junction structures.

According to still another aspect of the present disclosure, the series connection between each solar cell units is an electrical connection. The electrical connection is performed by applying a conductive substrate or by the following steps: depositing an insulting material to the gaps between each solar cell units; cutting the insulating material to form a filling space and filling a conductive material into the filling space.

According to still another aspect of the present disclosure, a large solar cell module is formed by repeatedly connecting the tandem solar cell structures in series, wherein the series connection of the tandem solar cell structure is performed by connecting a negative electrode of the respective solar cell units of one of the tandem solar cell structures to a positive electrode of the respective solar cell units of another one of the tandem solar cell structures.

### BRIEF DESCRIPTION OF THE DRAWINGS

The disclosure can be more fully understood by reading the following detailed description of the embodiment, with reference made to the accompanying drawings as follows:

FIG. 1 shows an elementary method of fabricating a tandem solar cell structure according to the embodiment of the present disclosure;

FIG. 2A is a schematic view showing a first process step of the tandem solar cell structure according to the embodiment of the present disclosure;

FIG. 2B is a schematic view showing a second process step of the tandem solar cell structure according to the embodiment of the present disclosure;

FIG. 2C is a schematic view showing a third process step of the tandem solar cell structure according to the embodiment of the present disclosure;

FIG. 2D is a schematic view showing a fourth process step of the tandem solar cell structure according to the embodiment of the present disclosure;

FIG. 2E is a schematic view showing a fifth process step of the tandem solar cell structure according to the embodiment of the present disclosure;

FIG. 2F is a schematic view showing a sixth process step of the tandem solar cell structure according to the embodiment of the present disclosure;

FIG. 2G is a schematic view showing a seventh process step of the tandem solar cell structure according to the embodiment of the present disclosure;

FIG. 2H is a schematic view showing an eighth process step of the tandem solar cell structure according to the embodiment of the present disclosure;

FIG. 2I is a schematic view showing a ninth process step of the tandem solar cell structure according to the embodiment of the present disclosure;

FIG. 3 shows an application method of the tandem solar cell structure; and

FIG. 4 shows n improvement of the tandem solar cell structure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

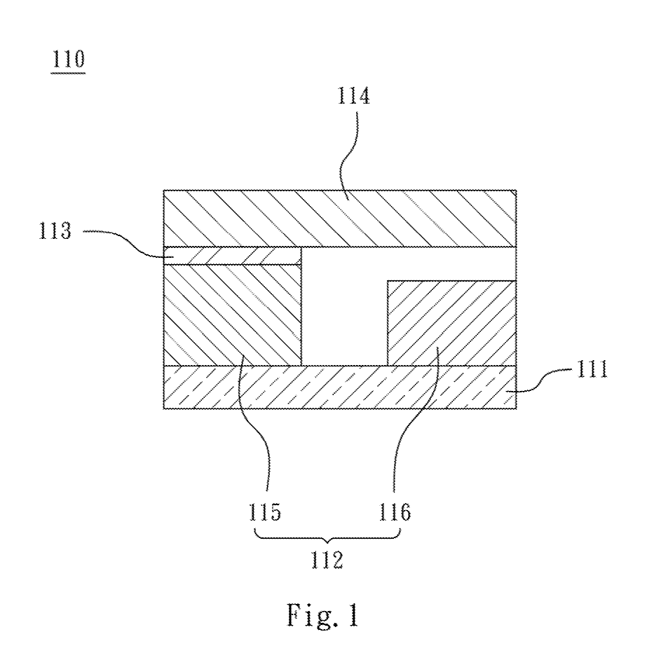

Referring to FIG. 1, a tandem solar cell structure 110 comprises a substrate 111, a bottom solar cell combination 112, a conductive layer 113 and a top solar cell 114. The bottom solar cell combination 112 is disposed on the substrate 111 The bottom solar cell combination 112 comprises a solar cell unit 115 and a solar cell unit 116. The solar cell unit 115 and the solar cell unit 116 are formed by cutting a solar cell body (not labeled). The conductive layer 113 is disposed between the top solar cell 114 and the solar cell unit 115. The top solar cell 114, the solar cell unit 115 and the solar cell unit 116 are connected in series electrically. The top solar cell 114 has higher bandgap energy value, and the solar cell unit 115 and the solar cell unit 116 have lower bandgap energy value. A solar radiation incident to the top solar cell 114 and the short wavelength region of the solar radiation is absorbed by the top solar cell 114. The long wavelength region of the solar radiation passes through the top solar cell 114 and is absorbed by the bottom solar cell combination 112. According to one embodiment of the disclosure, the top solar cell 114 covers the bottom solar cell combination 112 so that the usage efficiency of the solar radiation can be enlarged. The solar combination cell 112 is composed of a solar cell unit 115 and a solar cell unit 116, and the solar cell unit 115 and the solar cell unit 116 both has small contact area. As the current density is inverse proportional to the contact area, the current density of the bottom solar cell combination 112 is increased, thus the current mismatch between the top solar cell unit 114 and the bottom solar cell combination 112 can be reduced. Therefore, the short circuit current of the tandem solar cell structure 110 minimize the influence of the smaller short circuit current of the top solar cell 114, meanwhile, the open circuit voltage is increased owing to the series connection of the bottom solar cell combination 112. Consequently, the photoelectric conversion efficiency of the tandem solar cell structure can be enhanced.

A tandem solar cell structure for real case and fabrication method thereof is descried in the following embodiments. The tandem solar cell structure comprises an amorphous Silicon based p-i-n type top solar cell and a CIGS based p-n type bottom solar cell combination.

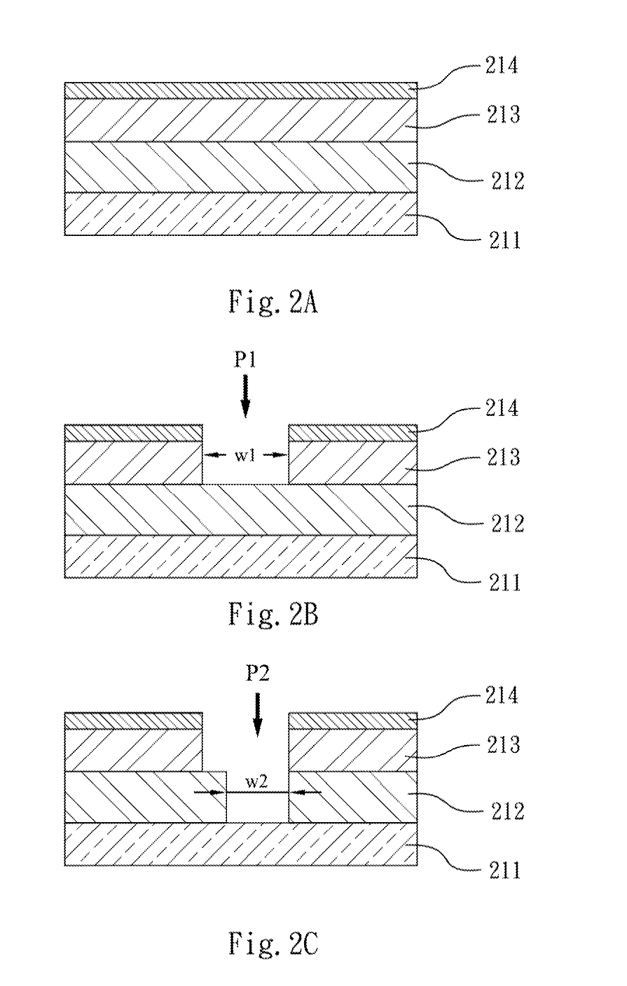

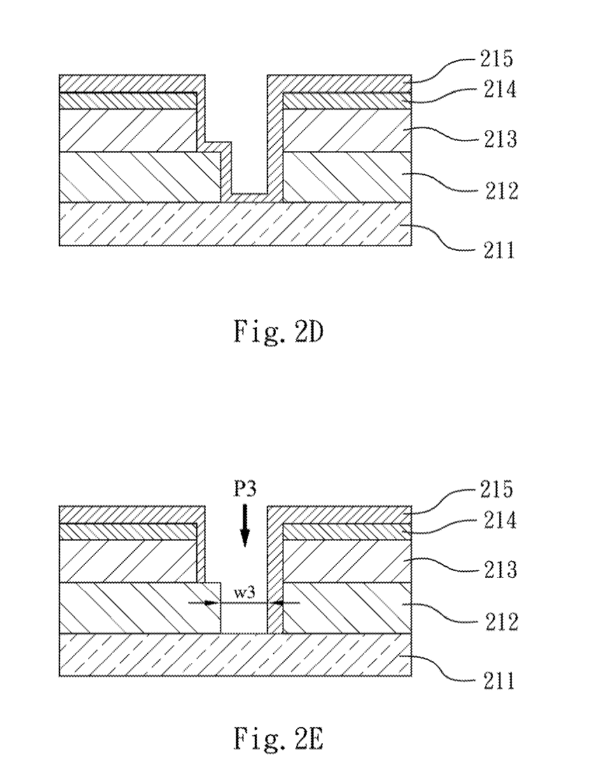

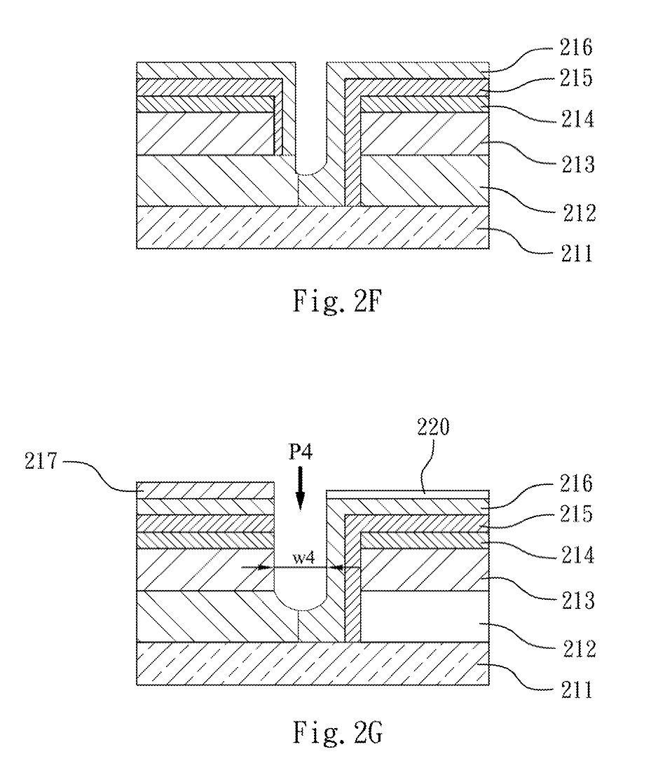

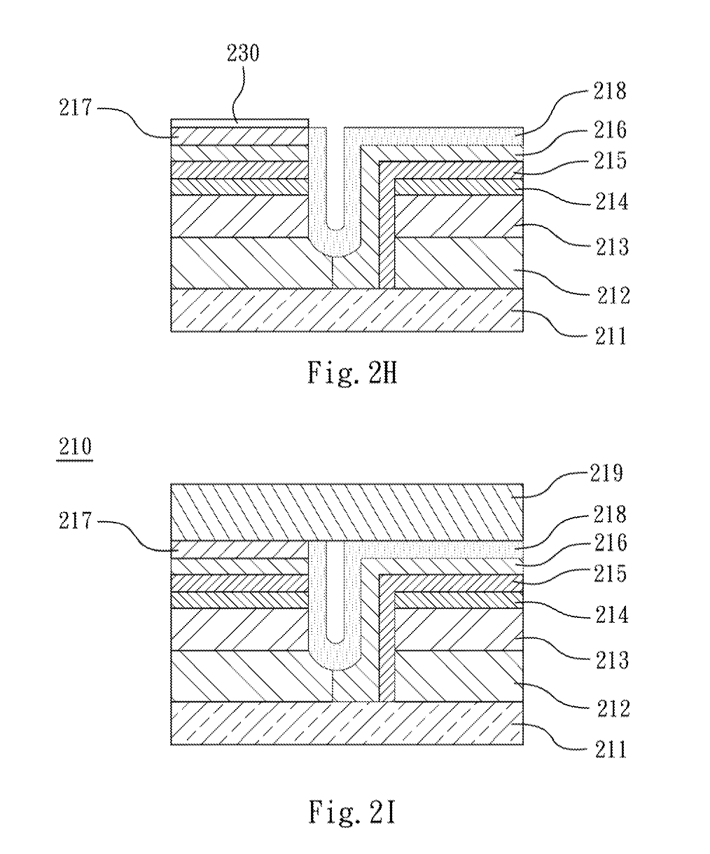

Referring to FIG. 2A, a Mo conductive metal layer 212 is deposited on a substrate 211 as a back-side electrode. A p-type CIGS layer 213 is then deposited on the Mo conductive metal layer 212. An n-type CdS layer 214 is deposited on the p-type CIGS layer 213 in order to form a p-n junction.

Referring to FIG. 2B, a laser scribing method is applied to the structure of FIG. 2A. A notch with a width W1 is formed in position P1 by cutting through the CdS layer 214 and the GIGS layer 213.

Referring to FIG. 2C, a laser scribing method is applied to the structure of FIG. 2B. A notch with a width W2 is formed in position P2 by cutting through the Mo conductive metal layer 212.

Referring to FIG. 2D, a first ZnO layer 215 is deposited on the structure of FIG. 2C.

Referring to FIG. 2E, a laser scribing method is applied to the structure of FIG. 2D. A notch with a width W3 is formed in position P3 by cutting through the first ZnO layer 215.

Referring to FIG. 2F, a transparent high conductive first ZnO:Al layer 216 is deposited on the structure of FIG. 2E.

Referring to FIG. 2G, a removable mask 220 is formed on the first ZnO:Al layer 216 of the right side of the solar cell body (not labeled). A laser scribing method is applied to cut through the first ZnO:Al layer 216 and a notch with a width W4 is formed in position P4. A second transparent and high conductive ZnO:Al layer 217 is deposited on the first ZnO:Al layer 216 of the left side of the solar cell body (not labeled).

Referring to FIG. 2H, a removable mask 230 is formed on the second ZnO:Al layer 217, and a second ZnO layer 218 is deposited.

Referring to FIG. 21, an a-Si based p-i-n type solar cell structure 219 is deposited on the structure of FIG. 2H. Thus, a tandem solar cell structure 210 is formed.

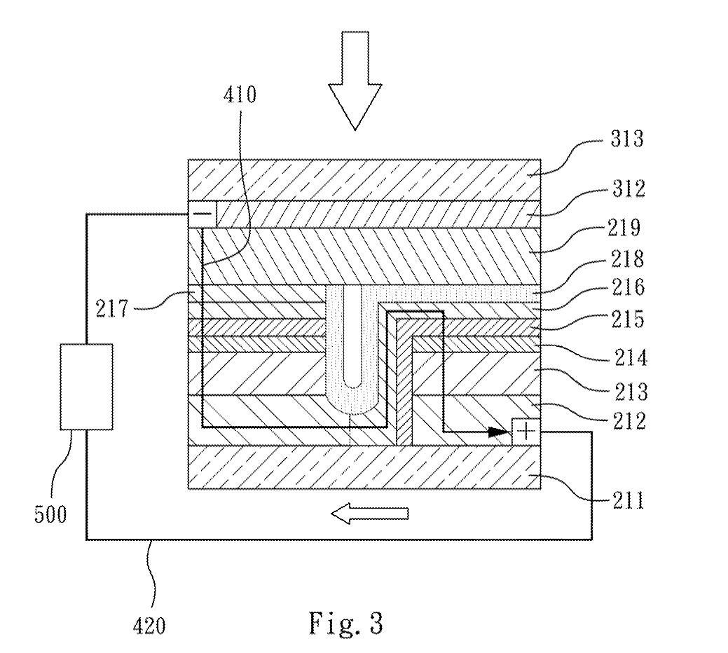

Referring to FIG. 3, a transparent high conductive ZnO:Al layer 312 is deposited on the a-Si based p-i-n type solar cell structure 219, and an optical transmission layer 313 is deposited on the ZnO:Al layer 312. The optical transmission layer 313 is made of glass or plastic, and the optical transmission layer 313 is equal to or larger than the a-Si based p-i-n type solar cell structure 219 in dimensions. A solar radiation incident through the optical transmission layer 313. The short wavelength region of the solar radiation is absorbed by the a-Si based p-i-n solar cell structure 219 and the long wavelength region of the solar radiation is absorbed by the CIGS based p-n type solar cell (not labeled) which is composed of the p-type CIGS layer 213 and n-type CdS layer 214. An inner current generated by the Photovoltaic Effect, and the inner current path is 410. In real application, an outer device 500 is connect to the Mo conductive metal layer 212 and the ZnO:Al layer 312. The outer current path is 420.

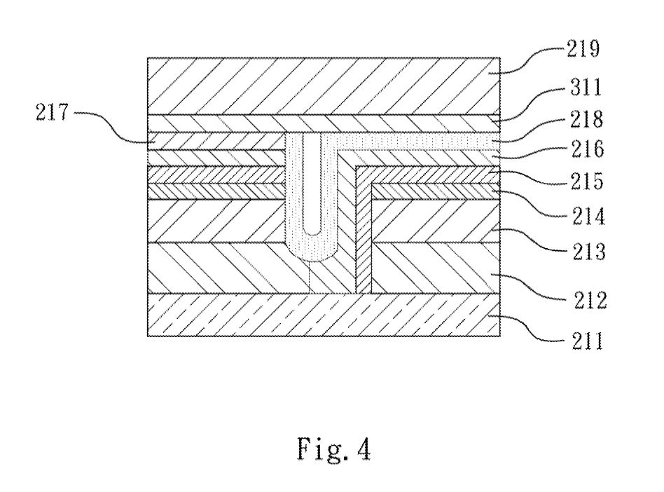

Referring to FIG. 4, an improvement of the tandem solar cell structure is provided. An transparent high conductive ZnO:Al layer 311 is further deposited between the second ZnO:Al layer 217 and the a-Si based p-i-n solar cell structure 219 of the tandem solar cell structure 210 of FIG. 21. A current loss can be reduced by the ZnO:Al layer 311 when the current pass through a hetero-junction.

Moreover, one of the embodiments shows a fabrication method to form a large solar cell module. The fabrication method of forming the large solar cell module comprises, connecting a top solar cell to a bottom solar cell units in series in order to form a tandem solar cell unit; coating a bottom electrode layer on the selected large area substrate; cutting the large area substrate in the number of pre-selected for the total number of tandem cell units; coating a tandem solar cell which not comprise a top transparent electrode layer on the large area substrate; cutting the tandem solar cell which not comprise the top transparent electrode layer into the bottom electrode slightly beside the previous cut of the bottom electrode layer; coating a transparent electrode layer on the pre-cut tandem solar cell and cutting the tandem cell structure comprise the as-coated transparent electrode layer into the bottom electrode layer. Therefore, a negative electrode of a first tandem solar cell unit is connected with a positive electrode of a second tandem solar cell unit, and a large solar cell module has selective electric voltage and power is formed by inter-connection mechanism, In other words, the concept of “nested” type of configuration in the complete electrical inter-connection is different from the conventional mechanism used in thin film solar cell module manufacturing processes.

The present disclosure provides a tandem solar cell structure that can reduce current mismatch and having high photoelectric conversion efficiency. The tandem solar cell structure comprises a top solar cell and a bottom solar cell combination. A solar radiation is incident to the top solar cell having larger bandgap energy, so the shorter wavelength region of the solar radiation is absorbed. Then, the longer wavelength region of the solar radiation passes through a tunneling conductive layer and reaches the bottom solar cell combination of the tandem solar cell structure. The longer wavelength region of the solar radiation is absorbed by the bottom solar cell combination. Therefore, a broadband of energy of the solar radiation can be absorbed. The bottom solar cell combination is consisting of a plurality of solar cell units which are cut from a standalone solar cell body. As the intensity of a current is inverse proportional to the dimension of a contact area, the current mismatch between the top solar cell and the bottom solar cell combination can be compensated by the solar cell units with small contact areas. Thus, the photoelectric conversion efficiency can be enhanced. And, owing to the solar cell units in the present disclosure is cut from a standalone solar cell body, manufacturing cost can be economized and fabrication efficiency can be increased. Furthermore, a large solar cell module can be formed by a series connection of each tandem solar cell structure.

It will be apparent to those ordinarily skilled in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A tandem solar cell structure, comprising:
a substrate;
a bottom solar cell combination disposed on the substrate and comprising a plurality of solar cell units connected in series with each other;
a conductive layer disposed on the bottom solar cell combination; and
a top solar cell disposed on the conductive layer and only connected with one of the solar cell units in series, and the top solar cell has a bandgap energy higher than that of the bottom solar cell units.

2. The tandem solar cell structure of claim , wherein the top solar cell is covering the bottom cell combination.

3. The tandem solar cell structure of claim 1, wherein the substrate is a transparent substrate.

4. The tandem solar cell structure of claim 3, wherein the transparent substrate is made of glass.

5. The tandem solar cell structure of claim 1, wherein the substrate is made of metal or organic materials.

6. The tandem solar cell structure of claim 1, wherein the substrate is a flexible substrate.

7. The tandem solar cell structure of claim 1, wherein the solar cell units of the bottom solar cell combination are formed by laser scribing, chemical etching or reactive ion etching.

8. The tandem solar cell structure of claim 1, wherein the solar cell units of the bottom solar cell combination are made of a III-V group semiconductor compound or a II-VI group semiconductor compound.

9. The tandem solar cell structure of claim 1, wherein the solar cell units of the bottom solar cell combination are made of organic semiconductor compounds.

10. The tandem solar cell structure of claim 1, wherein the solar cell units of the bottom solar cell combination are made of nanoscale materials.

11. The tandem solar cell structure of claim 1, wherein the solar cell units of the bottom solar cell combination are made of CuInGaSe-based materials or CuInSe-based materials.

12. The tandem solar cell structure of claim 1, wherein the conductive layer is made of conductive transparent oxide materials or thin and transparent metal materials.

13. The tandem solar cell structure of claim 1. wherein the conductive layer is a tunneling-junction layer.

14. The tandem solar cell structure of claim 1, wherein the fop solar cell is made of a-Si-based materials or CGS-based materials.

15. The tandem solar cell structure of claim 1, wherein the top solar cell has an a-Si/μc-SiC multi-junction structure.

16. A tandem solar cell fabrication method applicable to the tandem solar cell structure of claim 1, the tandem solar cell fabrication method comprising the to steps of:
forming a solar cell body;
cutting the solar cell body into a plurality of solar cell units, wherein a gap formed between each of the solar cell units;
connecting the solar cell units with each other in series to form a bottom solar cell combination; and
forming a top solar cell and connecting the top solar cell with one of the solar cell units in series.

17. The tandem solar cell fabrication method of claim 16, wherein the step of connecting in series is an electrical connecting in series.

18. The tandem solar cell fabrication method of claim 16, wherein the step of connecting the solar cell units in series is performed by applying a conductive substrate to the respective solar cell units.

19. The tandem solar cell fabrication method of claim 16, wherein the step of connecting the solar cell units in series is performed by the steps of:
depositing an insulating material into the gap between each of the solar cell units;
cutting the insulating material to form a filling space; and
filling a conductive material into the filling space.

20. The tandem solar cell fabrication method of claim 16, further comprising the step of:
forming a large solar cell module by repeatedly connecting the tandem solar cell structures in series which is performed by connecting a negative electrode of the respective solar cell units of one of the tandem solar cell structures to a positive electrode of the respective solar cell units of another one of the tandem solar cell structures.
